(19) United States
(12) Patent Application Publication
(10) Pub. No.: US 2015/0206907 A1
(43) Pub. Date: Jul. 23, 2015

(54) THIN FILM TRANSISTOR SUBSTRATE, DISPLAY PANEL AND DISPLAY DEVICE

(71) Applicant: Innolux Corporation, Chu-Nan (TW)

(72) Inventors: Shao-Wu HSU, Chu-Nan (TW); Yung-Hsin LU, Chu-Nan (TW); Jyun-Yu CHEN, Chu-Nan (TW)

(73) Assignee: INNOLUX CORPORATION, Chu-Nan (TW)

(21) Appl. No.: 14/596,746

(22) Filed: Jan. 14, 2015

(30) Foreign Application Priority Data
Jan. 17, 2014 (TW) 103101782

(51) Int. Cl. H01L 27/12; G02F 1/1362; G02F 1/1335; G02F 1/1368

(52) U.S. Cl. CPC H01L 27/1255; H01L 27/1222; H01L 27/1225; G02F 1/1368; G02F 1/136227; G02F 1/133514; G02F 1/133512; G02F 1/1336; G02F 1/136209; G02F 2001/133357

(57) ABSTRACT

A thin film transistor substrate is provided. The TFT substrate comprises a substrate, a first metal layer, a first insulating layer, a channel layer, a second insulating layer and a gate layer. The first metal layer is disposed on the substrate, and comprises a first portion and a second portion which are separated from each other. The first insulating layer is disposed on the first metal layer. The channel layer is disposed on the first insulating layer. The second insulating layer is disposed on the channel layer. The gate layer is disposed on the second insulating layer. The first portion and the second portion of the first metal layer partially overlap the channel layer.

This application claims the benefit of Taiwan application Serial No. 103101782, filed Jan. 17, 2014, the subject matter of which is incorporated herein by reference.

### BACKGROUND OF THE INVENTION

1. Field of the Invention

The invention relates in general to a thin film transistor (TFT) substrate, a display panel and a display device, and more particularly to a top-gate type TFT substrate, and a display panel and a display device using the same.

2. Description of the Related Art

Along with the rapid advance in the display technology, high-resolution display capable of processing digital signals and displaying more details has gradually become a main stream product. Liquid crystal display (LCD) panel with the advantages of low power consumption, slim thickness and light weight can be used in such high-resolution display.

Traditional thin film transistor (TFT) liquid crystal display (LCD) charges/discharges a pixel electrode by controlling a TFT so as to change the transmittance of the liquid crystal molecules corresponding to the pixel electrode. Of the variety of liquid crystal displays that are currently available, the most popular poly-silicon TFT is generally bottom-gate type TFT. However, the step of a channel layer which occurs during the manufacturing of bottom-gate type TFT will deteriorate its efficiency. Besides, the display region of a high resolution liquid crystal display needs to have a storage capacitance (Cst) to stabilize the voltage and avoid image flickering. However, the high resolution liquid crystal display with the bottom-gate type transistor, which disposes the storage capacitance electrode in the pixel region, not only deteriorates the efficiency of transistor but also decreases the aperture ratio of the display.

### SUMMARY OF THE INVENTION

The invention is directed to a thin film transistor (TFT) substrate and a display panel and a display device using the same. The pixel structure of the TFT substrate is capable of displaying high resolution images, and has an additional storage capacitance at a part of the TFT substrate parallel to the trace of the gate.

According to one embodiment of the present invention, a thin film transistor substrate is provided. The TFT substrate comprises a substrate, a first metal layer, a first insulating layer, a channel layer, a second insulating layer and a gate layer. The first metal layer is disposed on the substrate, and comprises a first portion and a second portion which are separated from each other. The first insulating layer is disposed on the first metal layer. The channel layer is disposed on the first insulating layer. The second insulating layer is disposed on the channel layer. The gate layer is disposed on the second insulating layer. The first portion and the second portion of the first metal layer partially overlap the channel layer.

According to another embodiment of the present invention, a display panel is provided. The display panel comprises the above TFT substrate, an opposite substrate and a liquid crystal layer. The opposite substrate is opposite to the TFT substrate. The liquid crystal layer is located between the TFT substrate and the opposite substrate.

According to an alternate embodiment of the present invention, a display device is provided. The display device comprises the above display panel and a backlight module. The backlight module is disposed on one side of the display panel adjacent to the TFT substrate.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 is a schematic diagram of a display device according to an embodiment of the invention.

FIG. 2A is a top view of a partial pixel structure of a TFT substrate according to an embodiment of the invention.

FIG. 2B is a cross-sectional view of the TFT substrate of FIG. 2A along a dotted line A-A′.

FIG. 3A is a schematic diagram of a display panel according to another embodiment of the invention.

FIG. 3B is a schematic diagram of a display panel according to an alternate embodiment of the invention.

FIG. 3C is a schematic diagram of a display panel according to another alternate embodiment of the invention.

### DETAILED DESCRIPTION OF THE INVENTION

A number of embodiments are disclosed below with accompanying drawings for elaborating the invention. It should be noted that the drawings are simplified so as to provide clear descriptions of the embodiments of the invention, and the scales used in the drawings are not based on the scales of actual products. However, the embodiments of the invention are for detailed descriptions only, not for limiting the scope of protection of the invention.

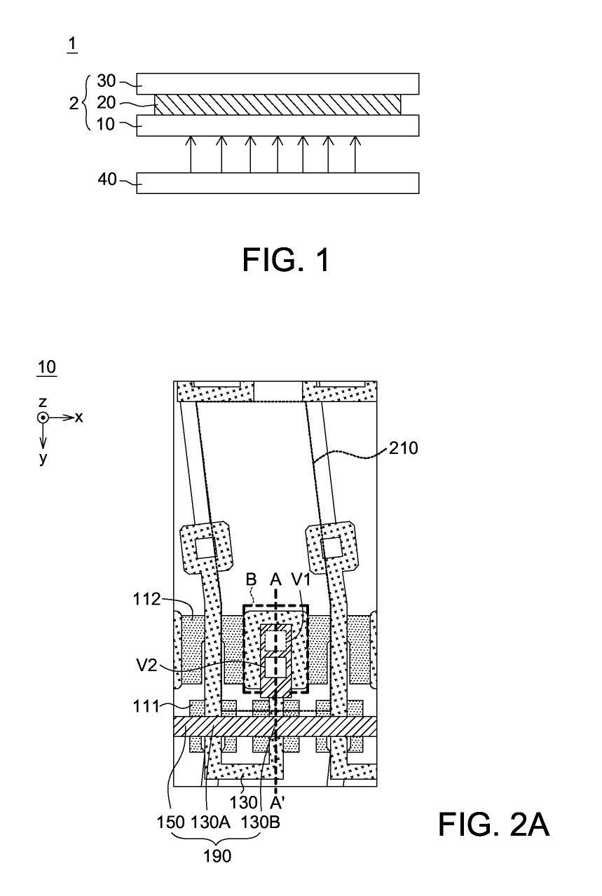

Referring to FIG. 1, a schematic diagram of a display device according to an embodiment of the invention is shown. The display device 1 comprises a display panel 2 and a backlight module 40. The display panel 2 is a liquid crystal display (LCD) panel, and includes a TFT substrate 10, a liquid crystal layer 20 and an opposite substrate 30. The liquid crystal layer 20 is located between the TFT substrate 10 and the opposite substrate 30. The transmittance of the liquid crystal layer 20 can be changed when the liquid crystal layer 20 is driven by a voltage. The opposite substrate 30 is opposite to the TFT substrate 10, and can be a color filter substrate, which enables the display panel 2 to display colors.

The TFT substrate 10, being a main element of the display panel 2, has a plurality of pixel structures. Each pixel structure corresponds to a pixel on the display panel 1, and the number of pixels per unit area is referred as resolution of the display panel 1 whose measurement is expressed as pixels per inch (PPI).

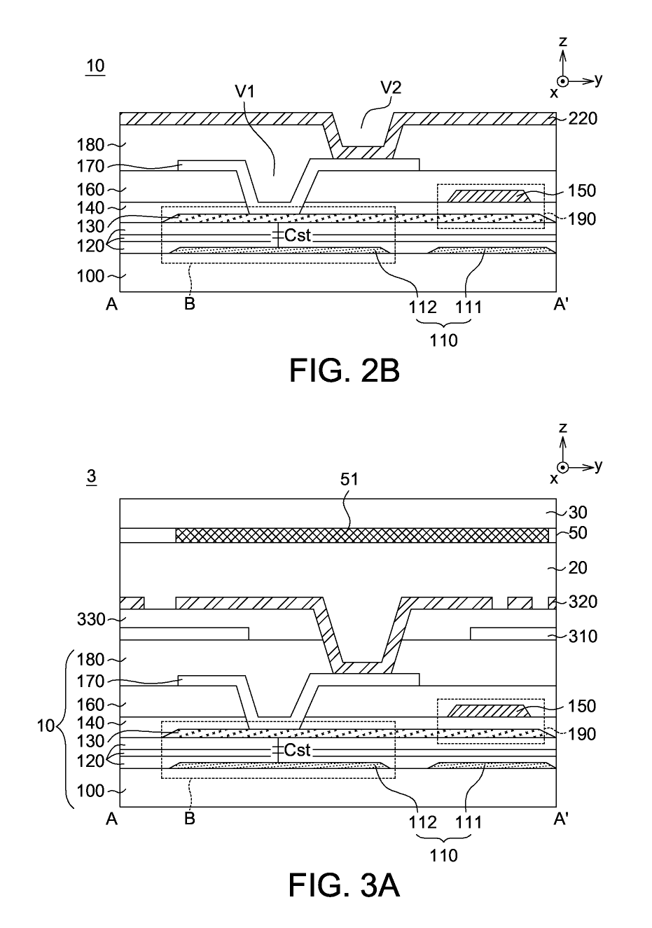

FIG. 2A and FIG. 2B are pixel structure of the TFT substrate 10 according to an embodiment of the invention. FIG. 2A is a top view of a partial pixel structure of a TFT substrate according to an embodiment of the invention. FIG. 2B is a cross-sectional view of the TFT substrate of FIG. 2A along a dotted line A-A′. As indicated in FIG. 2B, the TFT substrate 10 comprises a substrate 100, a first metal layer 110, a first insulating layer 120, a channel layer 130, a second insulating layer 140, a gate layer 150, a third insulating layer 160, a second metal layer 170, a planarization layer 180 and a pixel electrode 220.

Refer to both FIG. 2A and FIG. 2B. The substrate 100 is a transparent substrate. A first metal layer 110 patterned as two separate portions (first portion 111 and second portion 112) is disposed on the substrate 100. The first portion 111 of the first metal layer 110 is a metal light-shielding layer, which shields and prevents the light emitted by the backlight module (element 40 of FIG. 1) from radiating the transistor element (detailed descriptions are given below) and changing its electrical properties (such as leakage current). The second portion 112 of the first metal layer 110 can form an additional storage capacitance (detailed descriptions are given below) to increase the stability of the TFT substrate 10.

As indicated in FIG. 2A and FIG. 2B, the first insulating layer 120 covers the first metal layer 110, and the channel layer 130 is disposed on the first insulating layer 120. That is, the first insulating layer 120 separates the first metal layer 110 from the channel layer 130. In the present example, the first insulating layer 120 is a tri-layer structure. However, in alternative embodiments, the first insulating layer 120 can be a single-layer or multi-layer structure, and the invention does not specify the number of layers. Refer to FIG. 2A. The channel layer 130 disposed on the TFT substrate 10 has a U-shape. The design of U-shaped channel layer 130 increases aperture ratio and the number of pixels that can be disposed per unit area for implementing high resolution display. In an embodiment, the design of U-shaped circuit layout can achieve at least a resolution of 538 PPI. In another embodiment, the design of L-shaped circuit layout, which can only achieve a resolution of 500 PPI, can hardly be used for implementing in a high resolution display. Therefore, the TFT substrate 10 of the present embodiment can be used in high resolution display panel and display device.

The channel layer 130 can be made of a material such as indium gallium zinc oxide (IGZO), poly-silicon or the like. In the present embodiment, the channel layer 130 is made of poly-silicon and can be doped with different concentrations of dopants to provide different types of conductivity (such as P-type or N-type). In the present example, the channel layer 130, the first insulating layer 120, and the second portion 112 of the first metal layer 110 overlap along a normal direction of the substrate 100 (the z-axis) to form a storage capacitance Cst, thereby increasing the stability of the TFT substrate 10. The region B of FIG. 2A and FIG. 2B is where the channel layer 130 overlapping the second portion 112 of the first conducting layer 110. The channel layer 130 corresponds to the gate layer 150. The channel layer 130, the gate layer 150 and the second insulating layer 140 together form a part of a transistor element. In other example, one edge of the second portion 112 away from the first portion 111 may exceed or align one edge of the channel layer 130 away from the first portion 111 along inverse y-axis.

As indicated in FIG. 2A and FIG. 2B, the TFT substrate 10 of the present embodiment can further comprise a third insulating layer 160, a second metal layer 170 and a planarization layer 180 disposed on the gate layer 150. The third insulating layer 160, disposed on the gate layer 150 for protecting the gate layer 150, has a first contact hole V1 passing through the second insulating layer 140 and the third insulating layer 160 and exposing the channel layer 130 corresponding to the second portion 112 of the first metal layer 110. The second metal layer 170 is electrically connected to the channel layer 130 through the first contact hole V1. The planarization layer 180, disposed on the third insulating layer 160, has a second contact hole V2 exposing the second metal layer 170. The pixel electrode 220 is disposed on the planarization layer 180 and electrically connected to the second metal layer 170 through the second contact hole V2.

As indicated in FIG. 2A and FIG. 2B, the second insulating layer 140 covers the entire channel layer 130, and the gate layer 150 is disposed on the second insulating layer 140. That is, the second insulating layer 140 separates the channel layer 130 from the gate layer 150. The overlap region between the gate layer 150 and the channel layer 130 forms a part of transistor element 190 (the region where the gate layer 150 and the second insulating layer 140 overlapping the channel layer 130 in FIG. 2B). The channel layer 130 can have an L shape or a U shape. In FIG. 2A, the channel layer 130 is exemplified by a U shape. Since the U-shaped channel layer 130 overlaps the gate layer 150 by two regions 130A and 130B, the transistor element 190 has two channel regions 130A and 130B. Here, ‘overlapping’ refers to the channel layer 130 is over but not contacting the gate layer 150 along a normal direction of the substrate 100 (the z-axis). Such design reduces leakage current and increases the electrical properties of elements.

According to the TFT substrate of the disclosed embodiment, during the formation of a metal light-shielding layer, the metal light-shielding layer is patterned to form two separate portions 111 and 112, such that an additional storage capacitance can be formed on the TFT substrate to increase the stability of the TFT substrate without employing extra manufacturing process. Besides, such design can be used in the pixel structures of the U-shaped channel layer for manufacturing high resolution display panel and display device.

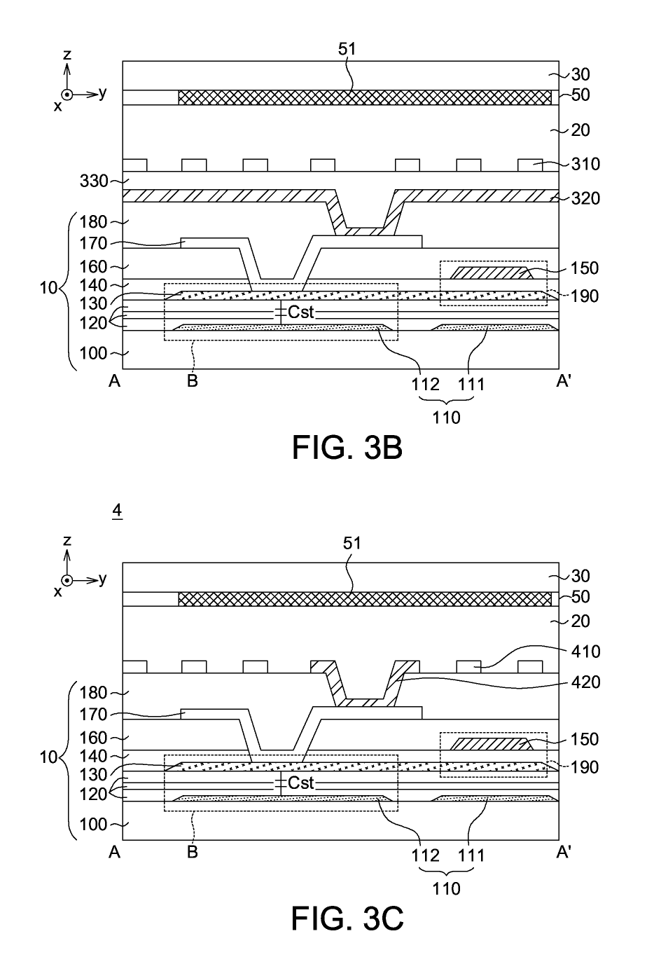

FIG. 3A to FIG. 3C are schematic diagrams of a display panel according to embodiments of the invention. FIG. 3A shows a fringe field switching (FFS) LCD panel. The display panel 3 includes a TFT substrate 10, a liquid crystal layer 20 and an opposite substrate 30 having a color filter layer 50. The color filter layer 50 provides a black matrix 51 (BM). Additionally, the TFT substrate 10 further comprises a common electrode layer 310, an inter-layered insulating layer 330 and a pixel electrode 320. The common electrode layer 310, the inter-layered insulating layer 330 and the pixel electrode 320 are sequentially formed on the planarization layer 180. The common electrode layer 310 and the pixel electrode 320 can generate a horizontal electrical field capable of changing the direction of the liquid crystal layer 20. In an alternate embodiment of the invention, the common electrode layer 310 and the pixel electrode 320 can be stacked in an opposite order as indicated in FIG. 3B.

The display panel 4 of FIG. 3C is an in-plane switching (IPS) LCD panel. The display panel 4 includes a TFT substrate 10, a liquid crystal layer 20 and an opposite substrate 30 having a color filter layer 50. Additionally, the TFT substrate 10 further comprises a common electrode layer 410 and a pixel electrode 420. The common electrode layer 410 and the pixel electrode 420 are sequentially formed on the planarization layer 180. The common electrode layer 410 and the pixel electrode 420 can generate a horizontal electrical field capable of changing the direction of the liquid crystal layer.

It should be noted that in the display panel of the disclosed embodiment, the storage capacitance Cst formed between the second portion 112 of the first metal layer 110 and the channel layer 130 is adjacent to the first contact hole V1 and the second contact hole V2, parallel to the circuit trace of the gate layer and located in a non-display region. As indicated in FIG. 3A to FIG. 3C, since the positions of the first contact hole V1 and the second contact hole V2 are shielded by the black matrix 51 of the opposite substrate, the disclosed design does not reduce the aperture ratio of the display panel. Besides, the additional storage capacitance Cst further reduces the occurrence of crosstalk.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A display panel, comprising:
a thin film transistor (TFT) substrate, the thin film transistor substrate comprising:
a substrate;
a first metal layer disposed on the substrate, wherein the first metal layer comprises a first portion and a second portion which are separated from each other;
a first insulating layer disposed on the first metal layer;
a channel layer disposed on the first insulating layer;
a second insulating layer disposed on the channel layer; and
a gate layer disposed on the second insulating layer,
wherein the first portion and the second portion of the first metal layer partially overlap the channel layer respectively.

2. The display panel according to claim 1, wherein the gate layer, the second insulating layer and the channel layer form a part of a transistor element.

3. The display panel according to claim 1, wherein the second portion of the first metal layer, a region of the channel layer partially overlapped by the second portion, and the first insulating layer together form a storage capacitance.

4. The display panel according to claim 1, wherein a region of the channel layer partially overlapped by the first portion and a region of the channel layer partially overlapped by the second portion are coupled.

5. The display panel according to claim 1, further comprising:
a third insulating layer disposed on the gate layer, wherein the third insulating layer has a first contact hole passing through the second insulating layer and the third insulating layer; and
a second metal layer disposed on the third insulating layer and electrically connected to the channel layer through the first contact hole.

6. The display panel according to claim 5, further comprising:
a planarization layer disposed on the third insulating layer and the second metal layer, wherein the planarization layer has a second contact hole; and
a pixel electrode disposed on the planarization layer and electrically connected to the second metal layer through the second contact hole.

7. The display panel according to claim 1, wherein the channel layer overlaps two regions of the gate layer, and the two regions are two channel regions.

8. The display panel according to claim 7, wherein the channel layer has a U shape.

9. The display panel according to claim 1, wherein the channel layer is made of indium gallium zinc oxide (IGZO) or poly-silicon.

10. The display panel according to claim 1, further comprising:
an opposite substrate opposite to the TFT substrate; and
a liquid crystal layer located between the TFT substrate and the opposite substrate.

11. The display panel according to claim 10, further comprising:
a color filter layer disposed on the opposite substrate.

12. The display panel according to claim 11, wherein the color filter layer comprises a black matrix layer located corresponding to the second portion of the first metal layer.

13. The display panel according to claim 10, wherein the display panel is an in-plane switching or a fringe field switching LCD panel.

14. A display device, comprising:
a display panel, comprising:
a thin film transistor (TFT) substrate, the thin film transistor substrate comprising:
a substrate;
a first metal layer disposed on the substrate, wherein the first metal layer comprises a first portion and a second portion which are separated from each other;
a first insulating layer disposed on the first metal layer;
a channel layer disposed on the first insulating layer;
a second insulating layer disposed on the channel layer;
a gate layer disposed on the second insulating layer,
an opposite substrate opposite to the TFT substrate; and
a liquid crystal layer located between the TFT substrate and the opposite substrate; and
a backlight module disposed on one side of the display panel adjacent to the TFT substrate;
wherein the first portion and the second portion of the first metal layer partially overlap the channel layer respectively.

15. The display device according to claim 14, wherein the first portion of the first metal layer shields and prevents the light emitted by the backlight module from radiating the transistor element.
